(19) United States
(12) Patent Application Publication
(10) Pub. No.: US 2026/0343958 A1
(43) Pub. Date: Oct. 29, 2026

(54) SEMICONDUCTOR DEVICE, SEMICONDUCTOR CHIP, AND SEMICONDUCTOR CIRCUIT

(71) Applicant: Mitsubishi Electric Corporation, Tokyo (JP)

(72) Inventors: Toshihiro IMASAKA, Tokyo (JP); Yu SEIKOBA, Tokyo (JP); Manabu YOSHINO, Tokyo (JP); Takuichiro SHITOMI, Tokyo (JP)

(73) Assignee: Mitsubishi Electric Corporation, Tokyo (JP)

(21) Appl. No.: 19/387,604

(22) Filed: Nov. 12, 2025

(30) Foreign Application Priority Data
Dec. 6, 2024 (JP) 2024-213377

(51) Int. Cl. H10D 30/83

(52) U.S. Cl. CPC H10D 30/83

(57) ABSTRACT

A semiconductor device includes a semiconductor substrate of a first conductivity type, a well region of a second conductivity type, a source region of the second conductivity type, a drain region of the second conductivity type, a first gate region of the first conductivity type, and a first diffusion layer of the second conductivity type. The semiconductor substrate has a first main surface in which the well region, the source region, the drain region, and the first gate region are formed. The drain region is far from the source region. The first gate region is disposed between the source region and the drain region. The first diffusion layer is far from the first main surface. An impurity concentration is higher in the first diffusion layer than in the well region. The first gate region and the first diffusion layer are closer to the source region than the drain region.

### CROSS REFERENCE TO RELATED APPLICATIONS

This nonprovisional application is based on Japanese Patent Application No. 2024-213377 filed on Dec. 6, 2024 with the Japan Patent Office, the entire contents of which are hereby incorporated by reference.

### BACKGROUND OF THE INVENTION

### Field of the Invention

The present disclosure relates to a semiconductor device, a semiconductor chip, and a semiconductor circuit.

### Description of the Background Art

As an alternative to a metal oxide semiconductor field effect transistor (MOSFET) structure having a high withstand voltage performance, a semiconductor device having a junction field effect transistor (JFET) structure has been known (for example, see Japanese Patent Laying-Open No. 2009-43923).

### SUMMARY OF THE INVENTION

In the semiconductor device having such a JFET structure, however, the gate potential does not need to be boosted, but the channel resistance may increase.

The present disclosure has been made to solve the above-described problems and an object thereof is to provide: a semiconductor device in which a channel resistance is suppressed; and a semiconductor chip including the semiconductor device.

A semiconductor device according to the present disclosure includes a semiconductor substrate of a first conductivity type, a well region of a second conductivity type, a source region of the second conductivity type, a drain region of the second conductivity type, a first gate region of the first conductivity type, and a first diffusion layer of the second conductivity type. The semiconductor substrate has a first main surface. The well region is formed in the first main surface. The source region is formed in the first main surface. The drain region is formed in the first main surface. The drain region is spaced apart from the source region. The first gate region is formed in the first main surface. The first gate region is disposed between the source region and the drain region. The first diffusion layer is formed at a distance from the first main surface. Each of the source region, the drain region, and the first gate region is disposed in the well region. An impurity concentration is higher in the first diffusion layer than in the well region. The first gate region is closer to the source region than the drain region. The first diffusion layer is closer to the source region than the drain region.

A semiconductor chip according to the present disclosure includes a first semiconductor circuit region, a second semiconductor circuit region, and the semiconductor device. The second semiconductor circuit region operates at a reference potential different from a reference potential in the first semiconductor circuit region. The semiconductor device is disposed on an outer periphery of the second semiconductor circuit region.

A semiconductor circuit according to the present disclosure includes: the semiconductor device; and a bootstrap capacitor connected to the semiconductor device.

The foregoing and other objects, features, aspects, and advantages of the present disclosure will become apparent from the following detailed description of the present disclosure when taken in conjunction with the accompanying drawings.

### BRIEF DESCRIPTION OF THE DRAWINGS

FIG. 1 is a schematic cross-sectional view of a semiconductor device according to a first embodiment.

FIG. 2 is a schematic plan view of a semiconductor substrate according to the first embodiment.

FIG. 3 is a schematic plan view of a first modification of the semiconductor substrate according to the first embodiment.

FIG. 4 is a schematic plan view of a second modification of the semiconductor substrate according to the first embodiment.

FIG. 5 is a schematic plan view of a third modification of the semiconductor substrate according to the first embodiment.

FIG. 6 is a schematic plan view of a fourth modification of the semiconductor substrate according to the first embodiment.

FIG. 7 is a schematic plan view of a fifth modification of the semiconductor substrate according to the first embodiment.

FIG. 8 is a schematic cross-sectional view of a semiconductor device according to a second embodiment.

FIG. 9 is a schematic cross-sectional view of a semiconductor device according to a third embodiment.

FIG. 10 is a schematic cross-sectional view of a sixth modification of the semiconductor device according to the third embodiment.

FIG. 11 is a schematic cross-sectional view of a semiconductor device according to a fourth embodiment.

FIG. 12 is a schematic cross-sectional view of a semiconductor device according to a fifth embodiment.

FIG. 13 is a schematic cross-sectional view of a semiconductor device according to a sixth embodiment.

FIG. 14 is a schematic cross-sectional view of a semiconductor device according to a seventh embodiment.

FIG. 15 is a schematic plan view of a semiconductor substrate according to a seventh embodiment.

FIG. 16 is a schematic plan view of a seventh modification of the semiconductor substrate according to the seventh embodiment.

FIG. 17 is a schematic cross-sectional view of a semiconductor device according to an eighth embodiment.

FIG. 18 is a schematic diagram of a semiconductor chip according to a ninth embodiment.

FIG. 19 is a schematic diagram of a semiconductor circuit according to a tenth embodiment.

### DESCRIPTION OF THE PREFERRED EMBODIMENTS

Hereinafter, embodiments of the present disclosure will be described. Unless otherwise specified, the same or corresponding portions are denoted by the same reference numerals in the accompanying drawings, and the description thereof will not be repeated.

### First Embodiment

### <Configuration of Semiconductor Device>

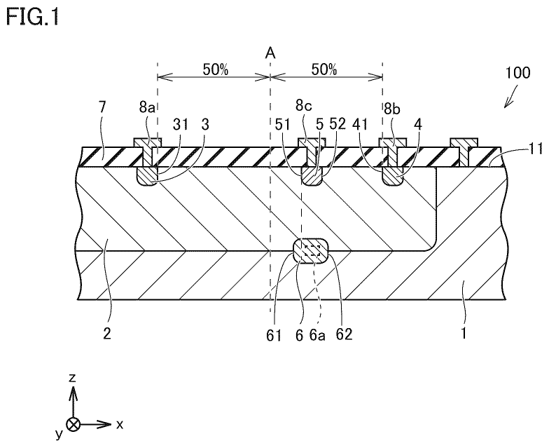

FIG. 1 is a schematic cross-sectional view of a semiconductor device 100 according to the first embodiment. Semiconductor device 100 shown in FIG. 1, which has a junction field effect transistor (JFET) structure, includes a semiconductor substrate 1, a well region 2, a source region 4, a drain region 3, a first gate region 5, a first diffusion layer 6, an oxide film 7, and electrodes 8a, 8b, and 8c.

In semiconductor device 100 according to the present first embodiment, each of semiconductor substrate 1 and first gate region 5 has a first conductivity type. In semiconductor device 100 according to the present first embodiment, each of well region 2, source region 4, drain region 3, and first diffusion layer 6 has a second conductivity type. In semiconductor device 100 according to the present first embodiment, the first conductivity type is a p-type, and the second conductivity type is an n-type.

In semiconductor device 100 according to the present first embodiment, well region 2 contains, for example, phosphorus (P) as an impurity. Each of drain region 3 and source region 4 contains, for example, arsenic (As) as an impurity. First gate region 5 contains, for example, boron (B) or difluoroboraneanion (BF₂) as an impurity. First diffusion layer 6 contains, for example, arsenic (As) or antimony (Sb) as an impurity.

The first conductivity type may be an n-type, and the second conductivity type may be a p-type.

As shown in FIG. 1, semiconductor substrate 1 has a first main surface 11.

Any material may be used as the material forming semiconductor substrate 1. The material forming semiconductor substrate 1 may be silicon (Si) or may be a compound containing silicon. Semiconductor substrate 1 may be a wide bandgap semiconductor such as silicon carbide (SiC) or gallium nitride (GaN), or may be a silicon-on-insulator (SOI) substrate.

Each of well region 2, drain region 3, source region 4, and first gate region 5 is formed in semiconductor substrate 1. Specifically, each of well region 2, drain region 3, source region 4, and first gate region 5 is formed in first main surface 11. Well region 2 is formed in a part of first main surface 11. Each of drain region 3, source region 4, and first gate region 5 is disposed in well region 2.

As shown in FIG. 1, drain region 3, source region 4, and first gate region 5 are spaced apart from each other. As shown in FIG. 1, an x-direction denotes a direction in which source region 4 is spaced apart from the drain region. A z-direction denotes a direction perpendicular to first main surface 11. The z-direction is perpendicular to the x-direction. A y-direction denotes a direction perpendicular to the x-direction and the z-direction. In other words, the x-direction and the y-direction are in-plane directions of first main surface 11.

Drain region 3 has a drain region end portion 31. In drain region 3, drain region end portion 31 is closest to source region 4 in the x-direction. Source region 4 has a source region end portion 41. In source region 4, source region end portion 41 is closest to drain region 3 in the x-direction.

First gate region 5 is disposed between source region 4 and drain region 3 in the x-direction. Specifically, first gate region 5 has a first gate end portion 51 and a second gate end portion 52. In first gate region 5, first gate end portion 51 is closest to drain region 3 in the x-direction. First gate end portion 51 faces drain region end portion 31. In first gate region 5, second gate end portion 52 is closest to source region 4 in the x-direction. Second gate end portion 52 faces source region end portion 41.

As shown in FIG. 1, first gate region 5 is closer to source region 4 than drain region 3 in the x-direction. From a different viewpoint, first gate region 5 is disposed between source region end portion 41 and a center A that is located between drain region end portion 31 and source region end portion 41 in the x-direction.

Oxide film 7 is provided on first main surface 11. Oxide film 7 covers an upper surface of well region 2, a part of an upper surface of drain region 3, a part of an upper surface of source region 4, and a part of an upper surface of first gate region 5. Electrode 8a is connected to a region of the upper surface of drain region 3, the region being exposed from oxide film 7. Electrode 8b is connected to a region of the upper surface of source region 4, the region being exposed from oxide film 7. Electrode 8c is connected to a region of the upper surface of first gate region 5, the region being exposed from oxide film 7. Oxide film 7 has an insulation property.

First diffusion layer 6 is formed in semiconductor substrate 1. The impurity concentration is higher in first diffusion layer 6 than in well region 2. First diffusion layer 6 is formed at a distance from first main surface 11 in the z-direction. First diffusion layer 6 may be disposed in contact with both well region 2 and semiconductor substrate 1 as shown in FIG. 1, may be disposed in well region 2, or may be in contact with first gate region 5.

Herein, semiconductor device 100 according to the present first embodiment is characterized in that first diffusion layer 6 is formed in the vicinity of first gate region 5 as shown in FIG. 1. First diffusion layer 6 is closer to source region 4 than drain region 3 in the x-direction. In semiconductor device 100 according to the present first embodiment, first diffusion layer 6 is disposed between drain region 3 and source region 4 in the x-direction. Thereby, first diffusion layer 6 functions as a drift layer when an ON current flows through drain region 3 and source region 4. In other words, the channel resistance in first gate region 5 is suppressed. Consequently, the on-resistance in semiconductor device 100 is suppressed.

As described above, the impurity concentration is higher in first diffusion layer 6 than in well region 2. Thus, in the case where first diffusion layer 6 is spaced apart from first main surface 11 in the z-direction such that first diffusion layer 6 is located below first gate region 5, a parasitic operation resulting from a vertical PNP structure formed of first gate region 5, well region 2, and semiconductor substrate 1 is suppressed.

In the case where the potential is lower in first gate region 5 than in source region 4, a depletion layer extends from first gate region 5, for example, while a current flows from source region 4 to drain region 3. Consequently, the channel resistance is increased.

Thus, a voltage close to the voltage applied to source region 4 is applied to first gate region 5 to thereby enable suppression of extension of the depletion layer. As a result, the on-resistance in semiconductor device 100 can be reduced during the ON state. On the other hand, the potential applied to first gate region 5 is switched during the OFF state to thereby enable suppression of the leakage current occurring during the OFF state. In this way, a plurality of different potentials may be applied to first gate region 5.

First diffusion layer 6 has a first diffusion layer end portion 61 and a second diffusion layer end portion 62. First diffusion layer end portion 61 is closest to drain region 3. Second diffusion layer end portion 62 is closest to source region 4. In the x-direction, second diffusion layer end portion 62 is located opposite to first diffusion layer end portion 61.

Then, the dimensions of semiconductor device 100 will be described. The thickness of semiconductor substrate 1 in the z-direction is 200 μm or more and 1000 μm or less. The depth of well region 2 (the distance from first main surface 11 to a lower end of well region 2 in the z-direction) is 3 μm or more and 10 μm or less. The depth of each of drain region 3 and source region 4 (the distance from first main surface 11 to a lower end of each of drain region 3 and source region 4 in the z-direction) is 0.5 μm or more and 2.0 μm or less. The depth of first gate region 5 (the distance from first main surface 11 to a lower end of first gate region 5 in the z-direction) is 1.0 μm or more and 3.0 μm or less. The depth of first diffusion layer 6 (the distance from first main surface 11 to a lower end of first diffusion layer 6 in the z-direction) is 5.0 μm or more and 20.0 μm or less.

The width of well region 2 in the x-direction is 50 μm or more and 300 μm or less. The width of each of drain region 3 and source region 4 in the x-direction is 1.0 μm or more and 10.0 μm or less. The width of first gate region 5 in the x-direction (the distance from first gate end portion 51 to second gate end portion 52) is 2 μm or more and 20 μm or less. The width of first diffusion layer 6 in the x-direction (the distance from first diffusion layer end portion 61 to second diffusion layer end portion 62) is 1 μm or more and 20 μm or less. Note that the depth and the width of each of well region 2, drain region 3, source region 4, first gate region 5, and first diffusion layer 6 may be changed according to the characteristics including the withstand voltage performance and the amount of current in semiconductor device 100.

The substrate resistance of semiconductor device 100 according to the present first embodiment is 50 Ωcm or more and 250 Ωcm or less. The impurity concentration in well region 2 is 1.0×10¹⁵ cm⁻³ or more and 5.0×10¹⁶ cm⁻³ or less.

The impurity concentration in each of drain region 3 and source region 4 is 1.0×10¹⁷ cm⁻³ or more and 5.0×10²⁰ cm⁻³ or less. The impurity concentration in first gate region 5 is 5.0×10¹⁶ cm⁻³ or more and 5.0×10¹⁸ cm⁻³ or less. The impurity concentration in first diffusion layer 6 is higher than that in well region 2 and is, for example, 5.0×10¹⁶ cm⁻³ or more and 1.0×10¹⁹ cm⁻³ or less. The impurity concentration in each of well region 2, drain region 3, source region 4, first gate region 5, and first diffusion layer 6 may be changed according to the characteristics including the withstand voltage performance and the amount of current in semiconductor device 100. In order to suppress the contact resistance between the upper surface of first gate region 5 and electrode 8c, the impurity concentration in the upper surface (the silicon surface) of first gate region 5 may be 1.0×10¹⁷ cm⁻³ or more and 5.0×10²⁰ cm⁻³ or less.

When well region 2 satisfies a reduced surface field (RESURF) condition (when the product of the impurity concentration (unit: cm⁻³) in well region 2 and the depth (unit: cm) of well region 2 is 6.9×10¹¹ cm⁻² or less), well region 2 is depleted while the withstand voltage is maintained during which a high potential is applied to drain region 3. Consequently, the withstand voltage performance in semiconductor device 100 according to the present first embodiment is improved.

However, even when well region 2 satisfies the RESURF condition, but if the diffusion layer including well region 2 and first diffusion layer 6 does not satisfy the RESURF condition, first diffusion layer 6 prevents depletion of well region 2, with the result that the withstand voltage performance in semiconductor device 100 abruptly decreases.

First diffusion layer 6 includes a first peak concentration region 6a. First peak concentration region 6a has an impurity concentration that is the highest in first diffusion layer 6. FIG. 1 shows a dotted line indicating first peak concentration region 6a.

As shown in FIG. 1, first peak concentration region 6a of first diffusion layer 6 may be disposed on the right side with respect to first gate end portion 51. From a different viewpoint, first peak concentration region 6a is located opposite to drain region 3 with respect to first gate end portion 51 in the x-direction. First peak concentration region 6a may be disposed between first gate end portion 51 and source region 4, or may overlap with source region 4 in a plan view of first main surface 11. Thereby, first diffusion layer 6 does not prevent depletion of well region 2. In other words, the withstand voltage performance in semiconductor device 100 according to the present first embodiment is improved.

Thereby, it is possible to obtain semiconductor device 100 in which the on-resistance is suppressed and high withstand voltage performance is achieved. If first peak concentration region 6a is disposed between first gate end portion 51 and source region 4 in the x-direction, first diffusion layer end portion 61 may be disposed between first gate end portion 51 and drain region 3 in the x-direction.

The direction of the current flowing through drain region 3 and source region 4 may be reversed.

### <Method of Manufacturing Semiconductor Device>

A method of manufacturing semiconductor device 100 according to the present first embodiment will be hereinafter described.

First, a step of preparing a substrate is performed. In this step, a substrate that constitutes semiconductor substrate 1 is first prepared.

Then, a step of forming first diffusion layer 6 is performed. In this step, first diffusion layer 6 is formed on the substrate by using an ion implantation method.

Then, a step of forming an epitaxial layer is performed. In this step, an epitaxial layer is formed on the substrate by epitaxial growth so as to cover first diffusion layer 6. Thereby, semiconductor substrate 1 formed of the substrate and the epitaxial layer is formed such that first diffusion layer 6 is disposed therein.

Then, a step of forming oxide film 7 is performed. In this step, oxide film 7 is formed by thermal oxidation on the upper surface (first main surface 11) of the epitaxial layer.

Then, a step of forming well region 2, drain region 3, source region 4, and first gate region 5 is performed. In this step, an opening through which first main surface 11 is exposed is first formed at a prescribed position of oxide film 7. Then, through the opening formed in oxide film 7, well region 2, drain region 3, source region 4, and first gate region 5 are formed by an ion implantation method on the upper surface (first main surface 11) of the epitaxial layer.

Then, a step of forming electrodes 8a, 8b, and 8c is performed. In this step, a metal such as aluminum (Al) is deposited to form a metal layer on oxide film 7 and first main surface 11. The metal layer is patterned to form electrodes 8a, 8b, and 8c that fill the openings formed in oxide film 7. Thereby, semiconductor device 100 shown in FIG. 1 can be obtained.

Note that high-energy ion implantation may be performed on semiconductor substrate 1. Thereby, first diffusion layer 6 can be formed in semiconductor substrate 1 without using epitaxial growth. Further, well region 2 may be formed by epitaxial growth.

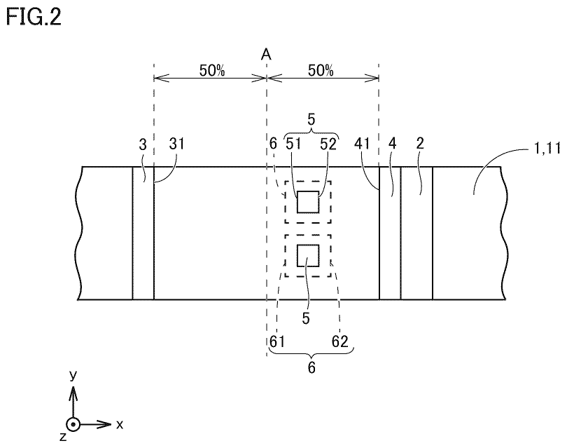

FIG. 2 is a schematic plan view of semiconductor substrate 1 according to the first embodiment. FIG. 2 shows a dotted line indicating the outline of first diffusion layer 6. As shown in FIG. 1, first diffusion layer 6 may overlap with first gate region 5 in a plan view of first main surface 11. Thereby, a parasitic operation resulting from a vertical PNP structure formed of first gate region 5, well region 2, and semiconductor substrate 1 is suppressed.

Further, first peak concentration region 6a may overlap with first gate region 5 in a plan view of first main surface 11. Thereby, a parasitic operation resulting from a vertical PNP structure formed of first gate region 5, well region 2, and semiconductor substrate 1 is further suppressed.

As shown in FIG. 2, each of first gate region 5 and first diffusion layer 6 may be intermittently formed. From a different viewpoint, first gate region 5 may include a plurality of first gate region portions that are spaced apart from each other in the y-direction. First diffusion layer 6 may include a plurality of first diffusion layer portions that are spaced apart from each other in the y-direction. In a plan view of first main surface 11, the first diffusion layer portions overlap with the respective first gate region portions.

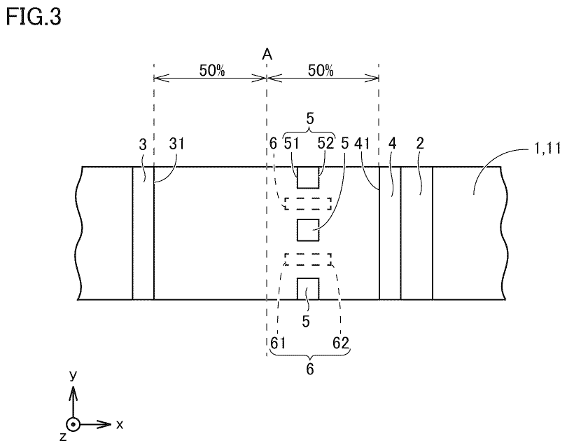

FIGS. 3 to 7 are schematic plan views of the first to fifth modifications of semiconductor substrate 1 according to the first embodiment. Each of FIGS. 3 to 7 corresponds to FIG. 2. Semiconductor substrate 1 shown in each of FIGS. 3 to 7 basically has the same configuration as that of semiconductor substrate 1 shown in FIGS. 1 and 2 and can achieve the same effect, but is different therefrom in terms of the configurations of first gate region 5 and first diffusion layer 6.

As shown in FIG. 3, in the first modification of semiconductor substrate 1 according to the first embodiment, each of first gate region 5 and first diffusion layer 6 is intermittently formed. In a plan view of first main surface 11, first diffusion layer 6 is spaced apart from first gate region 5 in the y-direction. In other words, in a plan view of first main surface 11, the first diffusion layer portions do not overlap with the respective first gate region portions. Thereby, first diffusion layer 6 is not disposed below first gate region 5, which results in a low impurity concentration in the area below first gate region 5. Therefore, a leakage current occurring during the OFF state can be suppressed.

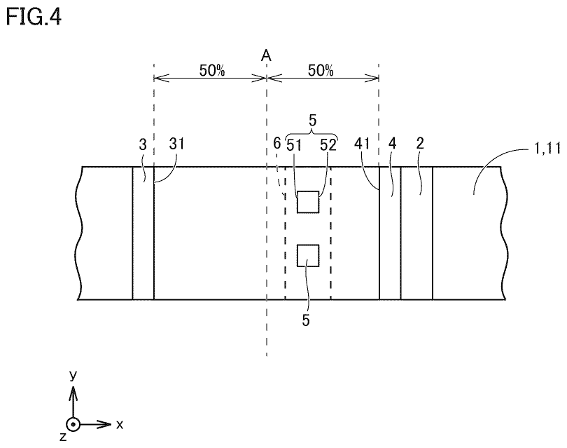

As shown in FIG. 4, in the second modification of semiconductor substrate 1 according to the first embodiment, first gate region 5 is intermittently formed. On the other hand, first diffusion layer 6 extends in the y-direction. In a plan view of first main surface 11, a plurality of first gate region portions overlap with one first diffusion layer 6. Thereby, the channel regions formed by first gate regions 5 are reduced. Consequently, first diffusion layer 6 is increased in area, so that the on-resistance in semiconductor device 100 is further suppressed.

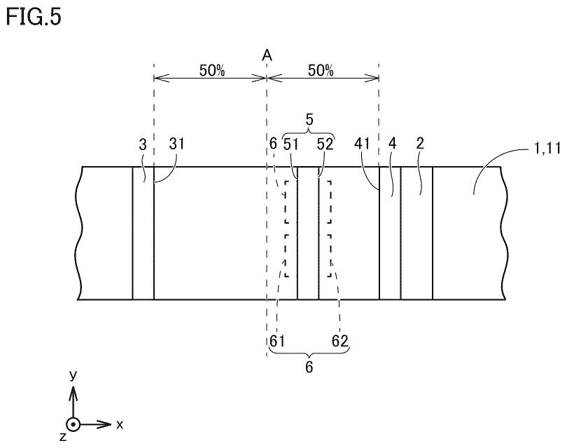

As shown in FIG. 5, in the third modification of semiconductor substrate 1 according to the first embodiment, first diffusion layer 6 is intermittently formed. On the other hand, first gate region 5 extends in the y-direction. In a plan view of first main surface 11, a plurality of first diffusion layer portions overlap with one first gate region 5. Thereby, the channel regions formed by first gate region 5 are increased. Consequently, first diffusion layer 6 is decreased in area, so that a leakage current occurring during the OFF state can be further suppressed.

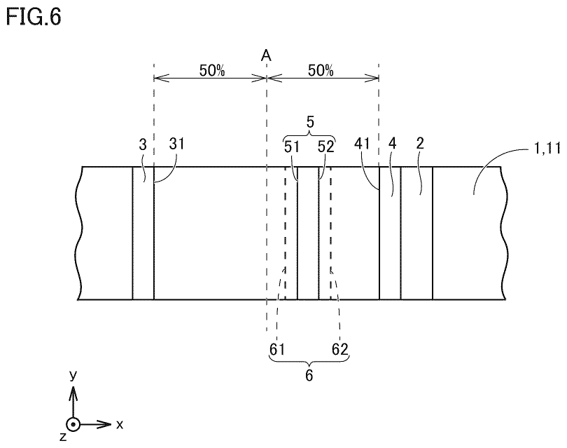

As shown in FIG. 6, in the fourth modification of semiconductor substrate 1 according to the first embodiment, first gate region 5 and first diffusion layer 6 extend in the y-direction. Thereby, when first gate region 5 and first diffusion layer 6 are misaligned, the influence on the electrical characteristics is smaller than in the case where each of first gate region 5 and first diffusion layer 6 is intermittently formed.

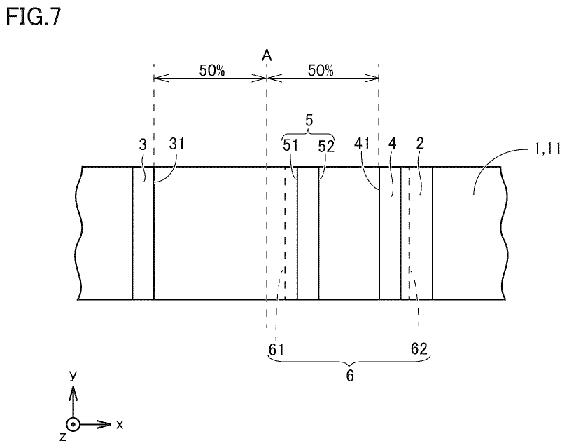

As shown in FIG. 7, in the fifth modification of semiconductor substrate 1 according to the first embodiment, first diffusion layer 6 overlaps with source region 4 in a plan view of first main surface 11. From a different viewpoint, in the plan view of first main surface 11, each of first gate region 5 and source region 4 is disposed between first diffusion layer end portion 61 and second diffusion layer end portion 62 in the x-direction. Thereby, the impurity concentration in an area below each of first gate region 5 and source region 4 becomes high between first gate region 5 and source region 4, so that the on-resistance is further suppressed.

### <Functions and Effects>

Semiconductor device 100 according to the present disclosure includes semiconductor substrate 1 of a first conductivity type, well region 2 of a second conductivity type, source region 4 of the second conductivity type, drain region 3 of the second conductivity type, first gate region 5 of the first conductivity type, and first diffusion layer 6 of the second conductivity type. Semiconductor substrate 1 has first main surface 11. Well region 2 is formed in first main surface 11. Source region 4 is formed in first main surface 11. Drain region 3 is formed in first main surface 11. Drain region 3 is spaced apart from source region 4. First gate region 5 is formed in first main surface 11. First gate region 5 is disposed between source region 4 and drain region 3. First diffusion layer 6 is formed at a distance from first main surface 11. Each of source region 4, drain region 3, and first gate region 5 is disposed in well region 2. The impurity concentration is higher in first diffusion layer 6 than in well region 2. First gate region 5 is closer to source region 4 than drain region 3. First diffusion layer 6 is closer to source region 4 than drain region 3.

Thereby, first diffusion layer 6 functions as a drift layer when an ON current flows through drain region 3 and source region 4. In other words, the channel resistance in first gate region 5 is suppressed. Consequently, the on-resistance in semiconductor device 100 is suppressed. Further, a parasitic operation resulting from a vertical PNP structure formed of first gate region 5, well region 2, and semiconductor substrate 1 is suppressed.

According to semiconductor device 100 described above, first diffusion layer 6 overlaps with first gate region 5 in a plan view of first main surface 11.

Thereby, the parasitic operation resulting from the vertical PNP structure formed of first gate region 5, well region 2, and semiconductor substrate 1 is further suppressed.

According to semiconductor device 100 described above, first diffusion layer 6 overlaps with source region 4 in a plan view of first main surface 11.

Thereby, the impurity concentration in an area below each of first gate region 5 and source region 4 is high, so that the on-resistance is further suppressed.

According to semiconductor device 100 described above, first diffusion layer 6 includes first peak concentration region 6a having the highest impurity concentration. In the plan view of first main surface 11, first peak concentration region 6a overlaps with first gate region 5.

Thereby, the parasitic operation resulting from the vertical PNP structure formed of first gate region 5, well region 2, and semiconductor substrate 1 is further suppressed.

According to semiconductor device 100 described above, first gate region 5 has first gate end portion 51 closest to drain region 3. First diffusion layer 6 includes first peak concentration region 6a having the highest impurity concentration. First peak concentration region 6a is located opposite to drain region 3 with respect to first gate end portion 51.

Thereby, first diffusion layer 6 does not prevent depletion of well region 2. In other words, the withstand voltage performance in semiconductor device 100 is improved.

According to semiconductor device 100 described above, a plurality of different potentials are applied to first gate region 5.

Thereby, the on-resistance in semiconductor device 100 can be reduced during the ON state. On the other hand, the potential applied to first gate region 5 is switched during the OFF state to thereby enable suppression of the leakage current occurring during the OFF state.

### Second Embodiment

### <Configuration of Semiconductor Device>

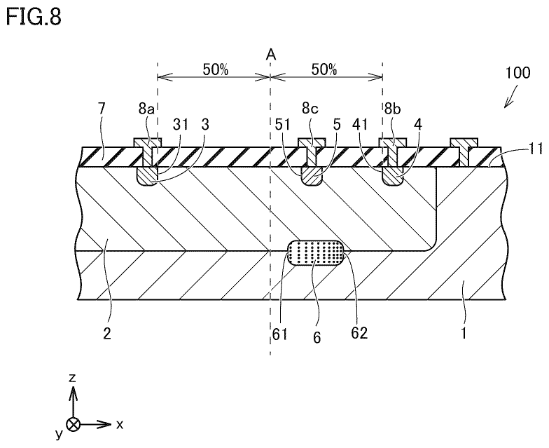

FIG. 8 is a schematic cross-sectional view of a semiconductor device 100 according to the second embodiment. FIG. 8 corresponds to FIG. 1. Semiconductor device 100 shown in FIG. 8 basically has the same configuration as that of semiconductor device 100 shown in FIGS. 1 and 2 and can achieve the same effect, but is different therefrom in that the impurity concentration in first diffusion layer 6 increases from first diffusion layer end portion 61 toward second diffusion layer end portion 62.

In other words, in first diffusion layer 6, the impurity concentration in first diffusion layer 6 is the lowest in the vicinity of first diffusion layer end portion 61. Thus, first diffusion layer 6 is easily depleted at the time when the withstand voltage is maintained. Consequently, the withstand voltage performance in semiconductor device 100 according to the present second embodiment is improved. Further, the impurity concentration in first diffusion layer 6 is the highest in the vicinity of second diffusion layer end portion 62. Therefore, the on-resistance in semiconductor device 100 can be suppressed as compared with the case where the impurity concentration in the entire first diffusion layer 6 is relatively low.

### <Functions and Effects>

According to semiconductor device 100 described above, first diffusion layer 6 has first diffusion layer end portion 61 and second diffusion layer end portion 62. First diffusion layer end portion 61 is closest to drain region 3. Second diffusion layer end portion 62 is closest to source region 4. The impurity concentration in first diffusion layer 6 increases from first diffusion layer end portion 61 toward second diffusion layer end portion 62.

Thereby, first diffusion layer 6 is easily depleted at the time when the withstand voltage is maintained. Consequently, the withstand voltage performance in semiconductor device 100 is improved. Thus, the on-resistance in semiconductor device 100 can be suppressed as compared with the case where the impurity concentration in the entire first diffusion layer 6 is relatively low.

### Third Embodiment

### <Configuration of Semiconductor Device>

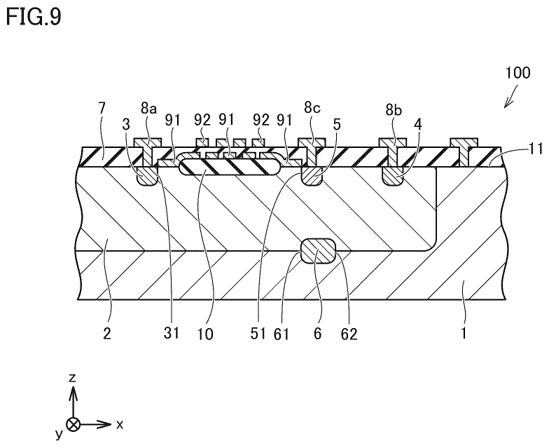

FIG. 9 is a schematic cross-sectional view of a semiconductor device 100 according to the third embodiment. FIG. 9 corresponds to FIG. 1. Semiconductor device 100 shown in FIG. 9 basically has the same configuration as that of semiconductor device 100 shown in FIGS. 1 and 2 and can achieve the same effect, but is different therefrom in that semiconductor device 100 includes an insulating layer 10 and a plurality of conductive layers 91 and 92.

Insulating layer 10 is provided on first main surface 11. Insulating layer 10 is disposed between source region 4 and drain region 3 in the x-direction. In semiconductor device 100 according to the present third embodiment, insulating layer 10 is disposed between first gate region 5 and drain region 3 in the x-direction. Insulating layer 10 may be formed by thermal oxidation of silicon, or may be formed by forming an oxide film.

Each of conductive layers 91 and 92 is disposed between first gate region 5 and drain region 3 in the x-direction. The plurality of conductive layers 91 are provided on insulating layer 10 and first main surface 11. Specifically, the plurality of conductive layers 91 are spaced apart from each other in the x-direction.

Among the plurality of conductive layers 91, conductive layer 91 closest to drain region 3 extends over insulating layer 10 and first main surface 11. Specifically, conductive layer 91 closest to drain region 3 extends in the x-direction from an area on insulating layer 10 to drain region end portion 31 of drain region 3. In other words, one end of conductive layer 91 closest to drain region 3 is disposed at the same position as drain region end portion 31 in the x-direction.

Among the plurality of conductive layers 91, conductive layer 91 closest to first gate region 5 extends over insulating layer 10 and first main surface 11. Specifically, conductive layer 91 closest to first gate region 5 extends in the x-direction from an area on insulating layer 10 to first gate end portion 51 of first gate region 5. In other words, one end of conductive layer 91 closest to first gate region 5 is disposed at the same position as first gate end portion 51 in the x-direction.

When a potential equivalent to that in drain region 3 is applied to conductive layer 91 closest to drain region 3 and a potential equivalent to that in source region 4 is applied to conductive layer 91 closest to source region 4, the plurality of conductive layers 91 and 92 are capacitively coupled to each other. Consequently, the potential in the upper surface of semiconductor device 100 becomes closer to the potential in first main surface 11. Thereby, the withstand voltage performance in semiconductor device 100 according to the present third embodiment is improved.

Oxide film 7 covers insulating layer 10 and the plurality of conductive layers 91. The plurality of conductive layers 92 are disposed on oxide film 7. The plurality of conductive layers 92 are spaced apart from each other in the x-direction. Thus, the plurality of conductive layers 91 and 92 are intermittently formed.

The material of the plurality of conductive layers 91 and 92 may be polysilicon or a metal such as aluminum. The plurality of conductive layers 91 and 92 are formed by a deposition process, a photoengraving process, and an etching process. The plurality of conductive layers 91 and 92 may be formed of other materials or may be formed by other methods.

The plurality of conductive layers 92 may be wiring layers used as electrodes in drain region 3 and source region 4.

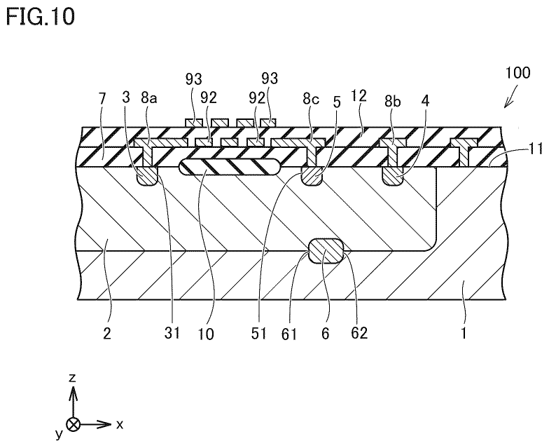

FIG. 10 is a schematic cross-sectional view of the sixth modification of the semiconductor device according to the third embodiment. FIG. 10 corresponds to FIG. 9. Semiconductor device 100 shown in FIG. 10 basically has the same configuration as that of semiconductor device 100 shown in FIG. 9 and can achieve the same effect, but is different therefrom in that semiconductor device 100 includes an oxide film 12 and a plurality of conductive layers 93.

Oxide film 12 is provided on oxide film 7. Oxide film 12 covers the plurality of conductive layers 92 and oxide film 7. As shown in FIG. 10, the plurality of conductive layers 91 are not disposed on insulating layer 10. Oxide film 12 may be formed by thermal oxidation of silicon.

The wiring layer used as each of electrodes 8a and 8b may be conductive layer 92. In a plan view of first main surface 11, one end of electrode 8a may extend in the x-direction on the upper surface of oxide film 7 such that one end of electrode 8a overlaps with a part of insulating layer 10. In the plan view of first main surface 11, one end of electrode 8c may extend in the x-direction on the upper surface of oxide film 7 such that one end of electrode 8c overlaps with a part of insulating layer 10.

Each of the plurality of conductive layers 93 is disposed between first gate region 5 and drain region 3 in the x-direction. The plurality of conductive layers 93 are spaced apart from each other in the x-direction.

### <Functions and Effects>

Semiconductor device 100 described above includes insulating layer 10 and the plurality of conductive layers 91. Insulating layer 10 is disposed between source region 4 and drain region 3. The plurality of conductive layers 91 are provided on insulating layer 10. The plurality of conductive layers 91 are spaced apart from each other.

Thereby, the plurality of conductive layers 91 are capacitively coupled to each other. Consequently, the potential in the upper surface of semiconductor device 100 becomes closer to the potential in first main surface 11. Thereby, the withstand voltage performance in semiconductor device 100 is improved.

### Fourth Embodiment

### <Configuration of Semiconductor Device>

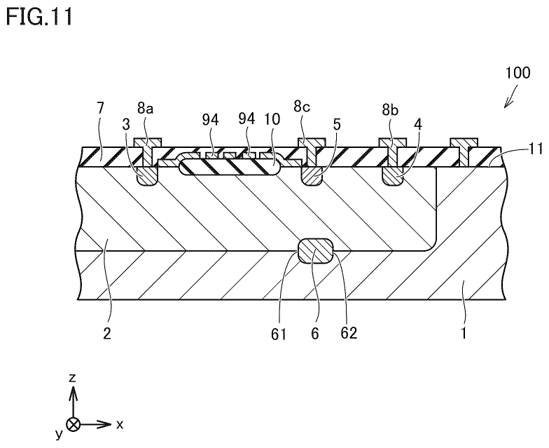

FIG. 11 is a schematic cross-sectional view of a semiconductor device 100 according to the fourth embodiment. FIG. 11 corresponds to FIG. 10. Semiconductor device 100 shown in FIG. 11 basically has the same configuration as that of semiconductor device 100 shown in FIG. 10 and can achieve the same effect, but is different therefrom in that a conductive layer 94 has a spiral shape in a plan view of first main surface 11. Specifically, conductive layer 94 is integrally formed unlike the plurality of conductive layers 91 that are formed intermittently.

Further, a potential equivalent to that in drain region 3 is applied to the end portion of conductive layer 94 closest to drain region 3 among spiral-shaped conductive layers 94, and a potential equivalent to that in source region 4 is applied to the end portion of conductive layer 94 closest to source region 4 among spiral-shaped conductive layers 94, with the result that the same effect as that in semiconductor device 100 according to the third embodiment can be achieved.

The material of conductive layer 94 may be polysilicon or a conductor. Another conductive layer may be provided above or below conductive layer 94.

### <Functions and Effects>

Semiconductor device 100 described above includes insulating layer 10 and conductive layer 94. Insulating layer 10 is disposed between source region 4 and drain region 3. Conductive layer 94 is provided on insulating layer 10. In a plan view of first main surface 11, conductive layer 94 has a spiral shape.

Thereby, the potential in conductive layer 94 continuously changes. Consequently, the potential in the upper surface of semiconductor device 100 becomes closer to the potential in first main surface 11. Thus, the withstand voltage performance in semiconductor device 100 is improved.

### Fifth Embodiment

### <Configuration of Semiconductor Device>

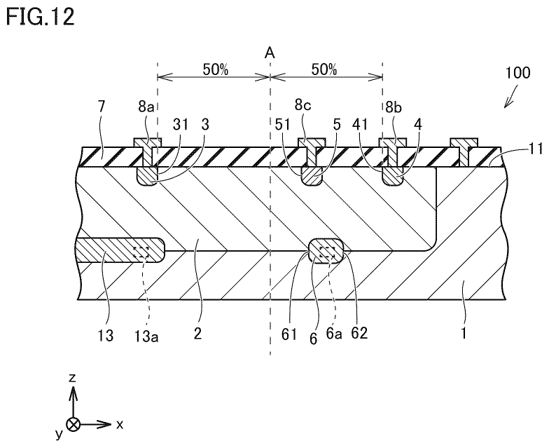

FIG. 12 is a schematic cross-sectional view of a semiconductor device 100 according to the fifth embodiment. FIG. 12 corresponds to FIG. 1. Semiconductor device 100 shown in FIG. 12 basically has the same configuration as that of semiconductor device 100 shown in FIGS. 1 and 2 and can achieve the same effect, but is different therefrom in that semiconductor device 100 includes a second diffusion layer 13 of a second conductivity type. In other words, the conductivity type of second diffusion layer 13 is the same as that of well region 2 and also the same as that of first diffusion layer 6. The impurity concentration is higher in second diffusion layer 13 than in well region 2.

Second diffusion layer 13 is formed in semiconductor substrate 1. Second diffusion layer 13 is formed at a distance from first main surface 11 in the z-direction.

In the step of forming first diffusion layer 6, second diffusion layer 13 may be formed together with first diffusion layer 6 by using an ion implantation method. Thereby, second diffusion layer 13 can be formed in the same step as the step of forming first diffusion layer 6, so that the process of manufacturing semiconductor device 100 according to the present fifth embodiment can be shortened.

By forming second diffusion layer 13 in the same step as the step of forming first diffusion layer 6, the depth of second diffusion layer 13 (the distance from first main surface 11 to a lower end of second diffusion layer 13 in the z-direction) may be the same as the depth of first diffusion layer 6 (the distance from first main surface 11 to a lower end of first diffusion layer 6 in the z-direction).

Second diffusion layer 13 includes a second peak concentration region 13a. Second peak concentration region 13a has an impurity concentration that is the highest in second diffusion layer 13. The distance from first main surface 11 to first peak concentration region 6a may be 0.9 times or more and 1.1 times or less as large as the distance from first main surface 11 to second peak concentration region 13a, or may be the same as the distance from first main surface 11 to second peak concentration region 13a.

Second diffusion layer 13 is closer to drain region 3 than first diffusion layer 6. In other words, from a different viewpoint, second diffusion layer 13 may be disposed on the left side with respect to center A.

Thereby, when well region 2 is depleted while the withstand voltage is maintained, second diffusion layer 13 suppresses the extension of the depletion layer. Consequently, the influence of the depletion layer is suppressed when a semiconductor circuit region is formed in the region on the left side of drain region 3 in FIG. 12 (the region opposite to source region 4 with respect to drain region 3).

### <Functions and Effects>

Semiconductor device 100 described above includes second diffusion layer 13 of the second conductivity type. Second diffusion layer 13 is formed at a distance from first main surface 11. The impurity concentration is higher in second diffusion layer 13 than in well region 2. Second diffusion layer 13 is closer to drain region 3 than first diffusion layer 6.

Thereby, when well region 2 is depleted while the withstand voltage is maintained, second diffusion layer 13 suppresses the extension of the depletion layer. Consequently, the influence of the depletion layer is suppressed when a semiconductor circuit region is formed in the region on the left side of drain region 3 in FIG. 12 (the region opposite to source region 4 with respect to drain region 3).

According to semiconductor device 100 described above, first diffusion layer 6 includes first peak concentration region 6a having the highest impurity concentration. Second diffusion layer 13 includes second peak concentration region 13a having the highest impurity concentration. The distance from first main surface 11 to first peak concentration region 6a is 0.9 times or more and 1.1 times or less as large as the distance from first main surface 11 to second peak concentration region 13a.

Thereby, second diffusion layer 13 can be formed in the same step as the step of forming first diffusion layer 6, so that the process of manufacturing semiconductor device 100 according to the present fifth embodiment can be shortened.

### Sixth Embodiment

### <Configuration of Semiconductor Device>

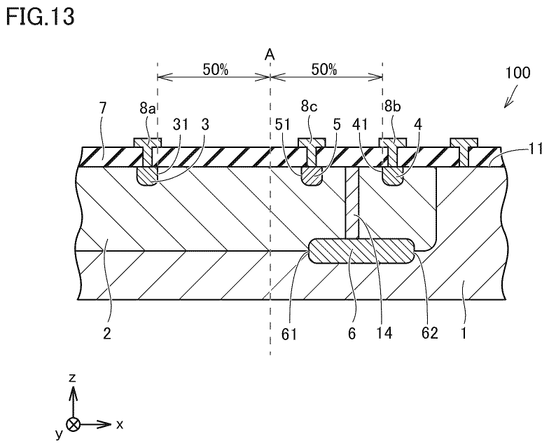

FIG. 13 is a schematic cross-sectional view of a semiconductor device 100 according to the sixth embodiment. FIG. 13 corresponds to FIG. 1. Semiconductor device 100 shown in FIG. 13 basically has the same configuration as that of semiconductor device 100 shown in FIGS. 1 and 2 and can achieve the same effect, but is different therefrom in that semiconductor device 100 includes a third diffusion layer 14 of the second conductivity type. In other words, the conductivity type of third diffusion layer 14 is the same as that of well region 2 and also the same as that of first diffusion layer 6. The impurity concentration is lower in third diffusion layer 14 than in well region 2.

Third diffusion layer 14 is formed in well region 2. Specifically, third diffusion layer 14 is formed in first main surface 11. Third diffusion layer 14 is in contact with first diffusion layer 6. Third diffusion layer 14 is disposed between source region 4 and first gate region 5. Third diffusion layer 14 may be in contact with or spaced apart from source region 4 or first gate region 5.

By forming third diffusion layer 14, the depletion layer in the vicinity of third diffusion layer 14 easily extends during the OFF state. Therefore, the leakage current occurring during the OFF state is further suppressed.

### <Functions and Effects>

Semiconductor device 100 described above includes third diffusion layer 14 of the second conductivity type. Third diffusion layer 14 is disposed between source region 4 and first gate region 5. The impurity concentration is lower in third diffusion layer 14 than in well region 2.

Thereby, the depletion layer in the vicinity of third diffusion layer 14 easily extends during the OFF state. Therefore, the leakage current occurring during the OFF state is further suppressed.

### Seventh Embodiment

### <Configuration of Semiconductor Device>

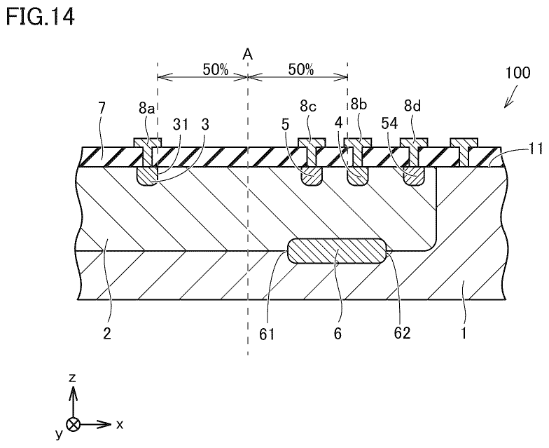

FIG. 14 is a schematic cross-sectional view of a semiconductor device 100 according to the seventh embodiment. FIG. 14 corresponds to FIG. 1. Semiconductor device 100 shown in FIG. 14 basically has the same configuration as that of semiconductor device 100 shown in FIGS. 1 and 2 and can achieve the same effect, but is different therefrom in that semiconductor device 100 includes a second gate region 54 of the first conductivity type. In other words, the conductivity type of second gate region 54 is the same as that of first gate region 5.

Second gate region 54 is formed in semiconductor substrate 1. Specifically, second gate region 54 is formed in first main surface 11. Second gate region 54 is disposed in well region 2. Electrode 8d is connected to a region in the upper surface of second gate region 54, the region being exposed from oxide film 7.

Second gate region 54 is located opposite to drain region 3 with respect to source region 4. In other words, second gate region 54 is located opposite to first gate region 5 with respect to source region 4.

By forming second gate region 54, the depletion layer in the vicinity of second gate region 54 easily extends during the OFF state. Therefore, the leakage current occurring during the OFF state is further suppressed.

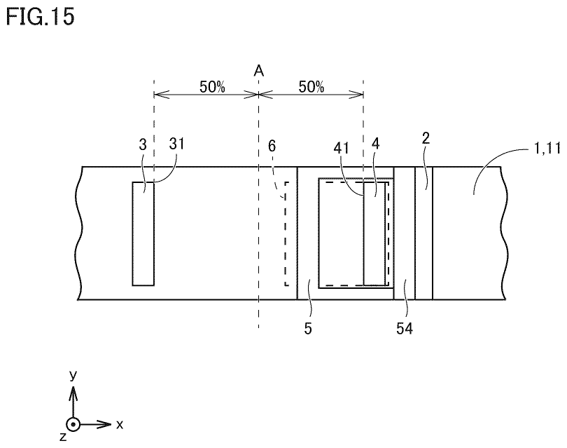

FIG. 15 is a schematic plan view of a semiconductor substrate 1 according to the seventh embodiment. FIG. 15 corresponds to FIG. 2. As shown in FIG. 15, first gate region 5 and second gate region 54 may be disposed on the outer periphery of source region 4. Specifically, in a plan view of first main surface 11, first gate region 5 may have a C-shape. First gate region 5 includes a first portion extending in the y-direction and a pair of second portions extending in the x-direction. The first portion is spaced apart from source region 4 in the x-direction. The pair of second portions each are spaced apart from source region 4 in the y-direction. The pair of second portions each have one end that may be in contact with second gate region 54.

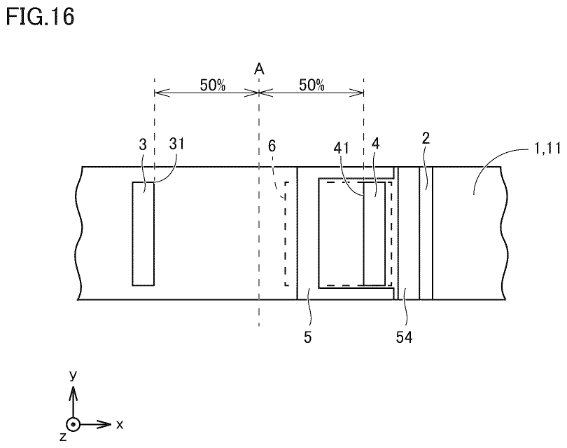

FIG. 16 is a schematic plan view of the seventh modification of semiconductor substrate 1 according to the seventh embodiment. As shown in FIG. 16, the pair of second portions each have one end that may be spaced apart from second gate region 54 in the x-direction. In other words, first gate region 5 and second gate region 54 may be spaced apart from each other.

The voltages applied to first gate region 5 and second gate region 54 may be the same or may be different from each other. In the case where the potentials applied to first gate region 5 and second gate region 54 are different from each other, the leakage current can be suppressed without lowering the current value between drain region 3 and source region 4 during the ON state.

### <Functions and Effects>

Semiconductor device 100 described above includes second gate region 54 of the first conductivity type. Second gate region 54 is formed in first main surface 11. Second gate region 54 is located opposite to drain region 3 with respect to source region 4. Second gate region 54 is disposed in well region 2.

Thereby, by forming second gate region 54, the depletion layer in the vicinity of second gate region 54 easily extends during the OFF state. Therefore, the leakage current occurring during the OFF state is further suppressed.

According to semiconductor device 100 described above, the voltages applied to first gate region 5 and second gate region 54 are different from each other.

Thereby, the leakage current can be suppressed without lowering the resistance value between drain region 3 and source region 4 during the ON state.

### Eighth Embodiment

### <Configuration of Semiconductor Device>

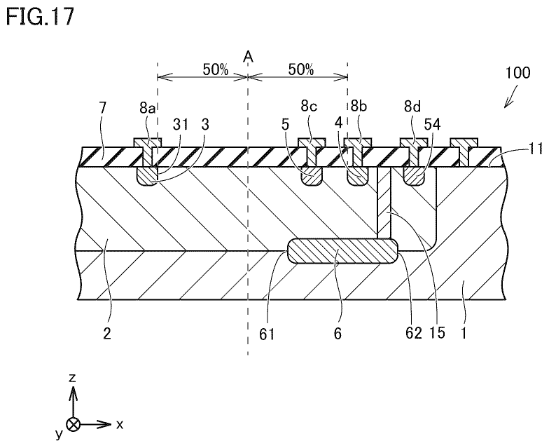

FIG. 17 is a schematic cross-sectional view of a semiconductor device 100 according to the eighth embodiment. FIG. 17 corresponds to FIG. 16. Semiconductor device 100 shown in FIG. 17 basically has the same configuration as that of semiconductor device 100 shown in FIGS. 15 and 16 and can achieve the same effect, but is different therefrom in that semiconductor device 100 includes a fourth diffusion layer 15 of the second conductivity type. In other words, the conductivity type of fourth diffusion layer 15 is the same as that of well region 2 and also the same as that of first diffusion layer 6. The impurity concentration is lower in fourth diffusion layer 15 than in well region 2.

Fourth diffusion layer 15 is formed in well region 2. Specifically, fourth diffusion layer 15 is formed in first main surface 11. Fourth diffusion layer 15 is in contact with first diffusion layer 6. Fourth diffusion layer 15 is disposed between source region 4 and second gate region 54. Fourth diffusion layer 15 may be in contact with or spaced apart from source region 4 or second gate region 54.

By forming fourth diffusion layer 15, the depletion layer in the vicinity of fourth diffusion layer 15 easily extends during the OFF state. Therefore, the leakage current occurring during the OFF state is further suppressed.

### <Functions and Effects>

Semiconductor device 100 described above includes fourth diffusion layer 15 of the second conductivity type. Fourth diffusion layer 15 is disposed between source region 4 and second gate region 54. The impurity concentration is lower in fourth diffusion layer 15 than in well region 2.

Thereby, the depletion layer in the vicinity of fourth diffusion layer 15 easily extends during the OFF state. Therefore, the leakage current occurring during the OFF state is further suppressed.

### Ninth Embodiment

### <Configuration of Semiconductor Device>

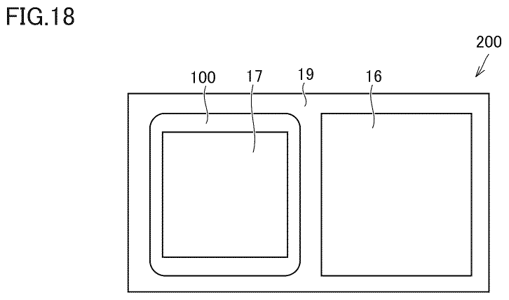

FIG. 18 is a schematic diagram of a semiconductor chip 200 according to the ninth embodiment. Semiconductor chip 200 shown in FIG. 18 includes a wafer 19, a first semiconductor circuit region 16, a second semiconductor circuit region 17, and semiconductor device 100 according to any one of the first to eighth embodiments. First semiconductor circuit region 16, second semiconductor circuit region 17, and semiconductor device 100 are formed on wafer 19. Second semiconductor circuit region 17 is spaced apart from first semiconductor circuit region 16. Second semiconductor circuit region 17 operates at a reference potential different from the reference potential in first semiconductor circuit region 16. Semiconductor device 100 is formed on the outer periphery of second semiconductor circuit region 17.

Thereby, first semiconductor circuit region 16 and second semiconductor circuit region 17 can be separated from each other until reaching the withstand voltage in semiconductor device 100. Consequently, the characteristics of semiconductor chip 200 are improved.

Semiconductor chip 200 according to the present ninth embodiment may be used, for example, as a semiconductor chip that forms a gate driver integrated circuit (IC) used for operating a power device.

Further, according to semiconductor chip 200 of the present ninth embodiment, the outer peripheral region of second semiconductor circuit region 17 is allowed to have functions of maintaining a withstand voltage and transmitting a signal.

### <Functions and Effects>

Semiconductor chip 200 according to the present disclosure includes first semiconductor circuit region 16, second semiconductor circuit region 17, and semiconductor device 100. Second semiconductor circuit region 17 operates at a reference potential different from the reference potential in first semiconductor circuit region 16. Semiconductor device 100 is disposed on the outer periphery of second semiconductor circuit region 17.

Thereby, semiconductor chip 200 is used as a semiconductor chip that forms a gate driver IC used for operating the power device. Further, in semiconductor chip 200, the outer peripheral region of second semiconductor circuit region 17 is allowed to have functions of maintaining a withstand voltage and transmitting a signal.

### Tenth Embodiment

### <Configuration of Semiconductor Device>

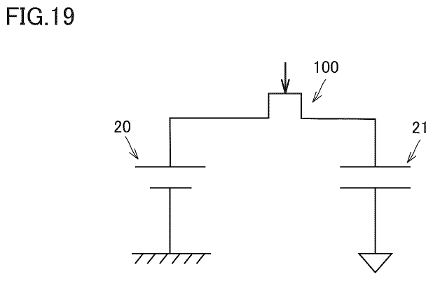

FIG. 19 is a schematic diagram of a semiconductor circuit according to the tenth embodiment. The semiconductor circuit shown in FIG. 19 includes a power supply 20, a bootstrap capacitor 21, and semiconductor device 100 according to any one of the present first to eighth embodiments. Power supply 20 and bootstrap capacitor 21 are connected to semiconductor device 100.

Power supply 20 causes a drive circuit to operate. Bootstrap capacitor 21 operates as an alternative to power supply 20. Incorporating semiconductor device 100 into the semiconductor circuit allows semiconductor device 100 to have two functions of adjusting the amount of the current and preventing backflow of the current. In other words, semiconductor device 100 operates as an alternative to a bootstrap resistor and a bootstrap diode. Thereby, the semiconductor circuit including semiconductor device 100 may function as a bootstrap circuit. Consequently, the configuration of the semiconductor circuit is simplified.

### <Functions and Effects>

The semiconductor circuit according to the present disclosure includes semiconductor device 100 as described above and bootstrap capacitor 21 connected to semiconductor device 100.

Thereby, semiconductor device 100 can be used as an alternative to the bootstrap resistor and the bootstrap diode. Consequently, the semiconductor circuit including semiconductor device 100 functions as a simplified bootstrap circuit.

Although the embodiments of the present disclosure have been described, it should be understood that the embodiments disclosed herein are illustrative and not restrictive in every respect. The scope of the present disclosure is defined by the terms of the claims, and is intended to include any modifications within the scope and meaning equivalent to the terms of the claims.

What is claimed is:

1. A semiconductor device comprising:
a semiconductor substrate of a first conductivity type, the semiconductor substrate having a first main surface;
a well region of a second conductivity type, the well region being formed in the first main surface;
a source region of the second conductivity type, the source region being formed in the first main surface;
a drain region of the second conductivity type, the drain region being formed in the first main surface and spaced apart from the source region;
a first gate region of the first conductivity type, the first gate region being formed in the first main surface and disposed between the source region and the drain region; and
a first diffusion layer of the second conductivity type, the first diffusion layer being formed at a distance from the first main surface, wherein
each of the source region, the drain region, and the first gate region is disposed in the well region,
an impurity concentration is higher in the first diffusion layer than in the well region,
the first gate region is closer to the source region than the drain region, and
the first diffusion layer is closer to the source region than the drain region.

2. The semiconductor device according to claim 1, wherein, in a plan view of the first main surface, the first diffusion layer overlaps with the first gate region.

3. The semiconductor device according to claim 2, wherein, in a plan view of the first main surface, the first diffusion layer overlaps with the source region.

4. The semiconductor device according to claim 1, wherein
the first diffusion layer includes a first peak concentration region having a highest impurity concentration, and
in a plan view of the first main surface, the first peak concentration region overlaps with the first gate region.

5. The semiconductor device according to claim 1, wherein
the first gate region has a first gate end portion closest to the drain region,
the first diffusion layer includes a first peak concentration region having a highest impurity concentration, and
the first peak concentration region is located opposite to the drain region with respect to the first gate end portion.

6. The semiconductor device according to claim 1, wherein a plurality of different potentials are applied to the first gate region.

7. The semiconductor device according to claim 1, wherein
the first diffusion layer has:
a first diffusion layer end portion closest to the drain region; and
a second diffusion layer end portion closest to the source region, and
the impurity concentration in the first diffusion layer increases from the first diffusion layer end portion toward the second diffusion layer end portion.

8. The semiconductor device according to claim 1, comprising:
an insulating layer disposed between the source region and the drain region; and
a plurality of conductive layers provided on the insulating layer, wherein
the plurality of conductive layers are spaced apart from each other.

9. The semiconductor device according to claim 1, comprising:
an insulating layer disposed between the source region and the drain region; and
a conductive layer provided on the insulating layer, wherein
in a plan view of the first main surface, the conductive layer has a spiral shape.

10. The semiconductor device according to claim 1, comprising a second diffusion layer of the second conductivity type, the second diffusion layer being formed at a distance from the first main surface, wherein
an impurity concentration is higher in the second diffusion layer than in the well region, and
the second diffusion layer is closer to the drain region than the first diffusion layer.

11. The semiconductor device according to claim 10, wherein
the first diffusion layer includes a first peak concentration region having a highest impurity concentration,
the second diffusion layer includes a second peak concentration region having a highest impurity concentration, and
a distance from the first main surface to the first peak concentration region is 0.9 times or more and 1.1 times or less as large as a distance from the first main surface to the second peak concentration region.

12. The semiconductor device according to claim 1, comprising a third diffusion layer of the second conductivity type, the third diffusion layer being disposed between the source region and the first gate region, wherein
an impurity concentration is lower in the third diffusion layer than in the well region.

13. The semiconductor device according to claim 1, comprising a second gate region of the first conductivity type, the second gate region being formed in the first main surface and located opposite to the drain region with respect to the source region, wherein
the second gate region is disposed in the well region.

14. The semiconductor device according to claim 13, wherein a voltage applied to the first gate region is different from a voltage applied to the second gate region.

15. The semiconductor device according to claim 13, comprising a fourth diffusion layer of the second conductivity type, the fourth diffusion layer being disposed between the source region and the second gate region, wherein
an impurity concentration is lower in the fourth diffusion layer than in the well region.

16. A semiconductor chip comprising:
a first semiconductor circuit region;
a second semiconductor circuit region that operates at a reference potential different from a reference potential in the first semiconductor circuit region; and
the semiconductor device according to claim 1, wherein
the semiconductor device is disposed on an outer periphery of the second semiconductor circuit region.

17. A semiconductor circuit comprising:
the semiconductor device according to claim 1; and
a bootstrap capacitor connected to the semiconductor device.
